(19) United States
(12) Patent Application Publication
(10) Pub. No.: US 2026/0235513 A1
(43) Pub. Date: Aug. 13, 2026

(54) Optical transmission measuring device and method of measurement

(71) Applicant: Hukseflux Holding B.V., Delft (NL)

(72) Inventor: Cornelis Jan van den Bos, Delft (NL)

(73) Assignee: Hukseflux Holding B.V., Delft (NL)

(21) Appl. No.: 19/153,618

(22) PCT Filed: Feb. 12, 2024
(86) PCT No.: PCT/EP2024/053499

§ 371 Date: Aug. 5, 2025

(30) Foreign Application Priority Data
Feb. 15, 2023 (NL) 2034159

(51) Int. Cl. G01N 21/59; G01N 21/94

(52) U.S. Cl. CPC G01N 21/59; G01N 21/94; G01N 2201/0221

(57) ABSTRACT

The present application shows a measuring device for measuring optical transmission through an object positioned in a measuring area between an external light source and the measuring device, the device comprising two sensors placed on a body, and situated in a measurement plane, the sensors having a substantially similar spectral and directional response, the measuring area and/or the body configured to move relative to each other between a first position in which a perpendicular projection of the measuring area onto the body does not overlap with any of the sensors, and a second position in which the projection of the measuring area overlaps with one sensor.

### FIELD OF THE INVENTION

The invention relates to a measuring device for determining optical transmission of an object positioned between the device and an external optical source. The invention further relates to a system comprising such a device and to a method of determining optical transmission and soiling loss of an object, in particular of a glass or plastic cover for a solar panel.

### DESCRIPTION OF THE RELATED ART

A device for the measurement of transmission of visible light through glass, plastic or other transparent or translucent objects is known from CN212872209U. The device comprises a light source and a light-receiving probe between which the object to be measured may be clamped.

Depending on the requirements of the transmission measurements, a light source with a different spectral emission and a sensor with a matching spectral response may be used.

However due to variations in the irradiance of the light source and typical degradation of the sensor, optical transmission measurements suffer from significant losses of accuracy. The sensor can have varying levels of cleanliness depending on the environment in which the sensor is used. Dust, sand, or debris will reflect a fraction of the light reaching the sensor and affect the result of the transmission measurements. Finally, temperature may also affect the sensor sensitivity.

A growing application of optical transmission measurements is the assessment of reduction in efficiency of photovoltaic (PV) panels due to soiling. Due to their outdoor exposure, the top glass or plastic layer of solar panels, which is first exposed to sunlight, will collect dirt. This soiling increases optical transmission losses as less light is transmitted to the solar cells, and therewith contributes to a decrease in the efficiency of the solar panel. As a result there is a need to quantify these losses, so as to know when to clean the solar panels.

The loss of transmission should be established as perceived by the PV cells for a light source with a typical solar spectrum. Soiling losses of a solar panel may be estimated by measuring the sunlight transmitted though this soiled glass or plastic cover alone, the cover sufficiently closely matching the properties of the cover of the PV panel, that have been exposed to the same environment as the PV panels, and are equally soiled.

A device for the measurement of optical transmission losses through a PV glass cover is known from MA41738A1. The device comprises sensors placed in boxes, the boxes closed at their top surface by one or more of the PV glass covers to be analyzed. When exposed to sunlight the sensors in the boxes measure the light that has been transmitted through the glass covers. The soiling loss can be estimated by comparing the transmittance of a soiled glass cover to the transmittance through the same glass cover when in its original clean condition.

Although the sensors of MA41738A1 may be protected from the dust, sand, or debris of the environment, they will still typically degrade over time and impact the estimated optical transmission. As a consequence, the results of the soiling loss measurements are inaccurate and the monitoring of a reduction in solar cell efficiency becomes unreliable. Consequently decisions making about solar panel cleaning therefore lacks a solid base.

Another device for soiling detection and transmission measurement is known from US 2020/0395892. This method requires use of voltage outputs of clean and soiled modules. It is understood that for transmission measurement with this method, all modules must be calibrated in the clean condition to have the same sensitivity to solar irradiance. Keeping sensors clean and calibrating them are both complex processes and the respective sensor outputs can deviate from one another with time.

It is therefore an object of the invention to provide a measuring device and a system of a compact and fail-safe construction with which the optical transmission of an object can be accurately measured. It is a further object of the invention to facilitate or eliminate the need for calibration and reduce the need to keep sensors clean. It is another object of the invention to provide methods of determination of the optical transmission and of determination of a soiling loss of a cover layer for photovoltaic panels, which provide accurate values.

### SUMMARY OF THE INVENTION

According to a first aspect of the invention, a measuring device is provided having the features according to claim 1. The device may be arranged for measuring optical transmission through an object positioned in a measuring area between an external light source and the measuring device, the device comprising two sensors placed on a body, and situated in a measurement plane, the sensors having a substantially similar spectral and directional response, the measuring area and/or the body configured to move between a first position in which a perpendicular projection of the measuring area onto the body does not overlap with any of the sensors, and a second position in which the projection of the measuring area overlaps with one sensor. The measuring device of the invention allows a multitude of optical measurements provided that the spectral properties of the sensors match the spectral properties of the external light source, which may be for instance a lamp or the sun, so that the combination of source and sensor measures a correct spectrally weighed transmission. The same device may therefore allow measurements of light from a plurality of different light sources, and does not require its own light source. As the measuring device uses a pair of sensors to measure optical transmission of an object, one sensor of the pair serves to measure the optical transmission through the object while the other sensor of the pair may remain outside of the projection of the object on the device and provide at all times a reference measurement of the light that is unobstructed by the object.

In particular, the outputs of the sensors when both exposed to the same light source can be compared on site in the first position so that their relative sensitivity is known, eliminating the need for a step of calibration. The control unit is thus adapted to calculate the value for the optical transmission of the object based on the changes in the ratio of the sensor outputs of the sensors. Therefore the measuring device provides for an accurate value of optical transmission eliminating the need for a separate calibration step, and improving the level of quality assurance of the optical transmission measurements. The level of accuracy obtained with the measuring device of the invention lifts off the requirements of the prior art to achieve a similar accuracy: the stability of the light source and the directional response, temperature response, stability and cleanliness of the sensors become irrelevant.

In an embodiment, the measuring device may comprise an actuator adapted to move the measuring area and/or the body between the first position and the second position. When the device is provided with an actuator, less to no human intervention is required in order to modify the relative positions of the body and of the object for the measurements. The actuator may be connected to either the measuring area and/or the body of the device and may be controlled so that it moves at pre-determined times. The actuator may be connected between the body and the object in order to move the body with respect to the object. The presence of an actuator results in a measuring device that facilitates measurement of optical transmission, independently of available human resources, geography and/or weather conditions.

In an embodiment, at least one of the measuring area and/or the body is provided with gripping means and/or a support structure to which a motion can be imparted to transport the measuring area and/or the body from the first position to the second position and vice-versa. Gripping means and/or a support structure facilitate movement of the measuring area and/or the body by a human and/or an actuator between the first and second positions. In fact, human and/or mechanical intervention may either be reduced or facilitated by the provision of gripping means or a support structure. For instance, a handle on the object may ease carrying and supporting of the object by an individual, or a stage or frame supporting the body at a certain height above the ground may facilitate remote control of the displacement of the sensors. The gripping means may comprise at least one of a handle, a projection, a clamp and the support structure may comprise at least a surface to support the weight of the body or measuring area. Other means known to the skilled person in the art to support or hold sensors, or support or hold objects of which the optical transmission is to be measured, fall within the scope of the invention.

In an embodiment, the actuator is an electro-mechanical or mechanical translator providing incremental movement to the measuring area and/or the body between the first and the second position. By providing incremental variation in their relative positions, the measuring device may allow for a precise control of positioning, with little to no human intervention, which is especially relevant when measuring the optical transmission of small objects.

In another embodiment, the measuring device may be a handheld instrument. A user can move the device between the first position and the second position in order to perform the measurement at a chosen location. In this case, the device may be provided with a switching arrangement in order to initiate capture of the first and second sensor outputs at the respective positions. The switching arrangement may be in the form of manual input by a button or other form of switch or position detecting device. The switch may be toggled to indicate the position of the measurement area relative to the object i.e. the first position and the second position. The switch may be configured to provide a signal to the control unit thereby indicating the conclusion of the first step of the measurement and the commencement of the second step of the measurement. The user may manually press or toggle this switch to advance the measurement steps.

Alternatively, in other embodiments, the switching arrangement may be automated. The partial occlusion of one of the pair of sensors by the object may result in a sufficient change in the sensor output from one sensor as compared to the other sensor. Here, the switching arrangement may be configured to provide a switching signal based on a relative change in the sensor outputs. In this way, the termination of the first step of the measurement and the commencement of the second step of the measurement may be inferred (without any user intervention).

In embodiments provided with an actuator, the switching arrangement may be functionally coupled to the actuator, whereby the position of the actuator may provide a switching signal. For instance, the first position and the second position may be the extremities of the actuator and the switching arrangement may detect them as such. In other embodiments, the switching arrangement may comprise position or proximity sensors, causing a switching signal to occur when the body is at or close to a specific first position and/or second position.

It will be apparent to the skilled person that the switching arrangement may be configured to provide the switching signal to the control unit. In summary, the device may be configured to provide a switching signal to distinguish between the first position and the second position of the body, measurement plane or sensors relative to the object. This feature facilitates advancement of the measurement steps for determining the optical transmission of the object.

In an embodiment, the sensors are Class C pyranometers according to ISO 9060 with a directional response deviation of maximum 0.3% relative to normal incidence. Typical variations of non-stabilised lamps and solar radiation can easily be averaged out. Such variations may be in the 5% per minute basis for mains-powered lamps, and in the 10% per minute basis for solar irradiance in semi-cloudless conditions. If deviations are larger, these may be rejected from the series of records used for analysis. However, if the measuring device comprises two sensors that are substantially the same such as two Class C pyranometers, the exact directional responses of the sensors do not matter.

In an embodiment, each of the sensors comprises a photodiode or a solar cell or a reference cell according to IEC 60904-2 made for example of, made of silicon, germanium, indium gallium arsenide, amorphous silicon (a-Si), copper-indium gallium diselenide (CIGS), copper-zinc tin sulfide/selenide (CZTSSe), cadmium telluride (CdTe), Perovskite and/or their alloys. The sensors can be selected to have a spectral response sufficiently matching that of the photovoltaic panels, so the loss of transmission may be established as perceived by solar cells for a light source with a typical solar spectrum. In this case the sensor may be made of a cell material used in solar cells and the external light source may be the sun. Other materials known to the skilled person to be suitable for use as solar cells may be used as the photodiode for the measuring device of the invention.

In an embodiment, at least one of the sensors is equipped with front optics such as a lens, a view limiting aperture or a diffuser. With additional optics, the field of view of any of the two sensors can be adjusted and any difference in lateral, vertical or angular position of one sensor to the other can be corrected for. As a result, the two sensors have a substantially identical, preferably identical directional response to light impinging their surface.

A practical embodiment of a measuring device used for analysis of silicon-based solar panels may employ two silicon photodiodes each equipped with a plastic diffusor, the combination having a spectral response sufficiently matching that of the solar panels. The diffusors, mounted next to one another in the same direction, create a substantially same directional response so that the exact alignment of the silicon photodiodes no longer matters.

In an embodiment, the control unit may be adapted to calculate a value of the optical transmission, T, of the object based on a first ratio of the sensor outputs, R_{ref}, when the measuring device is in the first position and on a second ratio of the sensor outputs, R, when the measuring device is in the second position. The device may further be provided with a suitable power supply for powering the control unit. By the provision of an internal power source such as a battery or PV cell on or within the device body, the measuring device becomes a stand-alone device. Measurement and final calculations of optical transmission and soiling loss may be performed with a compact device, that does not require external parts. This is particularly advantageous for measurements in remote areas, which is often the case for solar power plants.

In an embodiment, the body is further provided with a display connected to the control unit. User handling and decision making based on optical transmission measurements may be facilitated by an instantaneous display of data. The device may also be provided with user control means, which may be operatively connected to the control unit. In addition to the switching functions described above for initiating measurement, the user control means may provide other possibilities to interact with the device and with external resources. The skilled person will be familiar with suitable user control means, including graphical user interface (GUI), switches, buttons, keys and external controllers such as a handheld mobile device, mobile phone or tablet.

According to a second aspect of the invention, a system is provided comprising the measuring device and a transparent reference object. The measuring device may be arranged to calculate a value of the optical transmission of the reference object. This can then be used as a reference for other objects such as those exposed to similar conditions to the reference object. This is particularly useful in the context of large arrays of solar panels, where reference objects may be installed at particular locations adjacent to some of the panels. The reference objects may be arranged to be exposed to near identical soiling conditions to the solar panels. By evaluating the optical transmission or change in optical transmission of the reference objects an accurate estimation of the soiling of the solar panels may be determined.

The control unit may be adapted to calculate a value of the optical transmission, T, of the reference object based on a first ratio of the sensor outputs, R_{ref}, when the measuring device is in the first position and on a second ratio of the sensor outputs, R, when the measuring device is in the second position. The optical transmission may then be defined as T=R/R_{ref}. Accurate values of the optical transmission can be calculated by the control unit, storing and processing the ratio of values of light irradiance measured by the sensors in the first and second positions.

According to a third aspect of the invention, a method for determination of optical transmission, T, of an object positioned in a measuring area exposed to incident light radiation is disclosed having the features of claim 12. The method may be applicable both for direct and/or diffuse light and may comprise the steps of: providing a measuring device comprising two sensors placed on a body, the sensors situated in a measurement plane and having a substantially similar spectral response, arranging the measuring device at a first position relative to the measuring area so that both sensors are exposed to light of equal intensity, receiving first and second sensor outputs that are characteristic of a light intensity measured at each of the two sensors, moving the measuring device and/or the measuring area to a second position relative to the measuring area so that a first of the two sensors receives light transmitted through the object and a second of the two sensors receives incident light, receiving a third output that is characteristic of a light intensity transmitted through the object and measured by the first sensor and a fourth output that is characteristic of a light intensity measured by the second sensor and determining the optical transmission, T, of the object by evaluating the sensor outputs.

In general, the initial comparison will take place with both sensors exposed to incident light from the light source that has not passed through the object. It is however no excluded that the comparison in the first position takes place with both light sources receiving transmitted light. This may give an adequate result, especially when a uniform degree of soiling of the object is present.

In an embodiment, the method comprises positioning the measuring device relative to the measuring area so that a perpendicular projection of the measuring area initially does not overlap with either of the sensors, receiving first and second sensor outputs that are characteristic of a light intensity measured at each of the two sensors, moving the measuring device and/or the measuring area so that a perpendicular projection of the measuring area overlaps with a first of the two sensors of the measuring device, receiving a third output that is characteristic of a light intensity transmitted through the object and measured by the first sensor, and a fourth output that is characteristic of a light intensity measured by the second sensor, calculating a ratio, R_{ref} of the first and second outputs and a ratio, R, of third and fourth outputs, calculating the optical transmission, T, of the object using T=R/R_{ref}.

As the measurement procedure only uses the ratio R of the sensor outputs, and establishes the reference R_{ref} before every measurement, the sensors do not need to be clean and do not need to have been calibrated in the clean condition. It is also of little consequence if the sensors are unstable within the typical degradation levels. These two effects, if they do not lead to sensitivity losses of more than 50%, do not lead to significant loss of accuracy. Other measurements may be added for increased quality assurance, for example both sensors under the object, or a comparison to R_{ref} measured at an earlier time.

In an embodiment, the step of arranging the measuring device relative to the measuring area further comprises providing an angle of between 45 and 90° between the measurement plane and incident light radiation. The position of the source and the measuring device relative to the object matters. For example, in case of soiling loss measurements of solar panels, the measurement should be performed at high angles of incidence of the direct solar radiation on the measurement plane of the measuring device. An angle of incidence of light of between 45 and 90 degrees on a solar panel represents the situation around midday so that the measured transmission represents the situation where the energy production of such solar panels is at its peak.

According to a further aspect of the invention, a method of determining a soiling loss of a photovoltaic panels is provided, by determining the optical transmission of a transparent reference object mounted adjacent to the photovoltaic panel, the method comprising performing the steps described above to determine the optical transmission, T, of the reference object. For a reference object mounted adjacent to and oriented in the same manner as the photovoltaic panel, the transmission through the reference object may be assumed to be related to the transmission through the cover layer of the photovoltaic panel. This can provide an excellent approximation of the soiling loss of the panel.

The reference object may be a glass or a plastic cover layer that has been mounted adjacent and exposed to the same environmental soiling as the photovoltaic panel. It will be understood that care should be taken to ensure that the reference object is indeed exposed to the same conditions for the same time period as the photovoltaic panel that it is desired to assess, since minor differences in position, weather and ambient effects can lead to deviation. The reference object may have a front surface that is exposed to incident light and soiling and a rear surface of the reference object that is protected from soiling.

The soiling loss of the reference object may be calculated by determining the optical transmission, T, of the reference object and repeating the steps to determine the optical transmission, T_{clean}, of the same reference object in a clean condition. The soiling loss may be calculated using 100 (T_{clean}−T)/T_{clean}. When the result of the calculated soiling loss exceeds a predetermined threshold, a user, cleaning protocol and/or a cleaning device may be implemented to clean cover layers of photovoltaic panels in the photovoltaic power plant. The user may be informed by a monitoring device to which the results of the calculation have been transmitted.

Transmission measurements may be performed at multiple representative locations over the power plant. In this way the distribution of transmission losses over the photovoltaic power plant may be mapped. The measuring device offers the possibility to have many measurement points around a photovoltaic power plant at a relatively low cost. At each location a reference object may be installed and a user may move between reference locations with a single e.g. hand-held measuring device. Alternatively, a system comprising a reference object and measuring device may be installed as a unit at each location. For such a system, the measuring device may be mounted at a rear surface of the reference object and can be actuated to cause at least one of the light sensors to extend from behind the reference object and be exposed to incident radiation. The light sensors and the rear surface of the reference object may thus be protected from soiling.

### BRIEF DESCRIPTION OF THE DRAWINGS

An embodiment of a measuring device, a system comprising such a device and methods of measurement will by way of non-limiting example be described in detail with reference to the accompanying drawings. In the drawings:

FIG. 1 shows a perspective view of a measuring device for determining optical transmission of an object in accordance with the present invention;

FIG. 2 shows a perspective view of a stand-alone measuring device for determining optical transmission of an object in accordance with the present invention;

FIG. 3 shows a schematic view of a system comprising the device of FIG. 1 for determining optical transmission of an object in accordance with the present invention;

FIG. 4A shows a perspective view of the measuring device in use in a first step of determining optical transmission of an object in accordance with the present invention;

FIG. 4B shows a perspective view of the measuring device in use in a second step of determining optical transmission of an object in accordance with the present invention;

FIG. 5 shows a flowchart of a method of determining optical transmission in accordance with the present invention.

FIG. 6 shows a flowchart of a method of determining soiling loss in accordance with the present invention.

The devices, systems and features thereof are shown schematically and not drawn to scale.

### DETAILED DESCRIPTION OF THE INVENTION

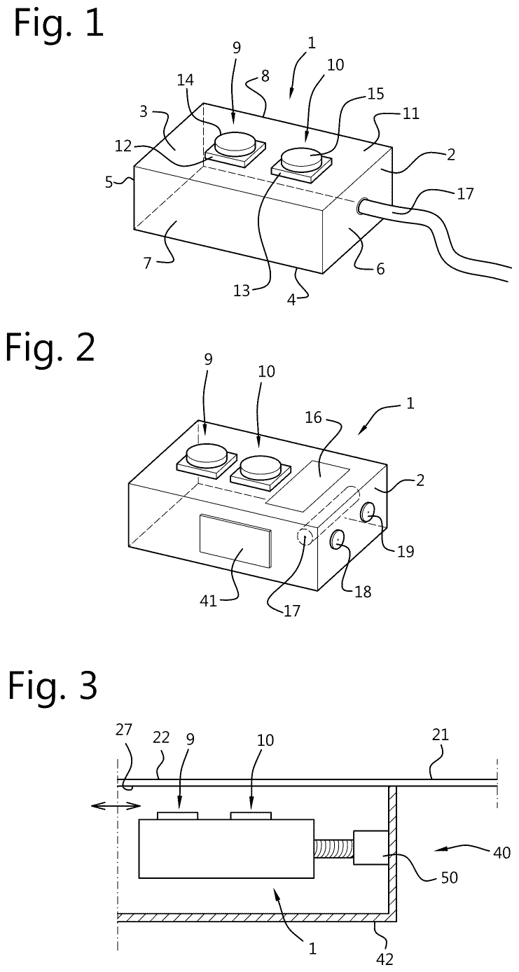

FIG. 1 shows a perspective view of a measuring device 1 for determining optical transmission of an object in accordance with an embodiment of the present invention. The device 1 comprises a body 2 with at least a measurement plane 11, and two sensors 9, 10 on the measurement plane operable to measure incident light from an external light source (not shown) that has travelled through the object to be analysed. The spectral properties of the sensors 9, 10 match the spectral properties of the external light source.

The body 2 is provided with at least one power cable 17 for connection to an external power source (not shown). Further connections to external electronics such as to a control unit may be provided on the body (not shown).

Each of the sensors 9, 10 measures both direct and diffuse light. The body 2 comprises at least one predominantly flat surface 3 on which the sensors 9, 10 are positioned. The body may comprise a plurality of other surfaces 4, 5, 6, 7, 8. The predominantly flat surface 3 on which the sensors are positioned is further referred to as measurement plane 11. Both sensors 9, 10 on the measurement plane 11 have a substantially similar spectral response and similar directional response. The sensors 9, 10 may be placed anywhere on the measurement plane 11, as long they have a substantially similar exposure of their surface area to light. Each of the sensors 9, 10 comprise a light sensing surface 12, 13, which may be a photodiode, for example a silicon photodiode sensitive in the 0.3 to 0.7 micrometre range, converting photons into an output signal, in case of a photodiode an electrical current or voltage. Other light sensing elements known to the person skilled in the art may be used depending on the spectral properties of the external light source. The sensors 9, 10 have a substantially similar field of view between 1.5 and 3 pi sr. Each of the sensors 9, 10 is provided with a diffuser 14, 15 on top of the light sensing surface 12, 13, the diffuser 14, 15 adjusting the directional response of the sensors 9,10. Other examples of such front optics to adjust the directional response of the sensors 9, 10 include a lens or a view limiting aperture. In other embodiments, only one or none of the sensors of the measuring device is equipped with such front optics.

FIG. 2 shows a perspective view of a measuring device 1 for determining optical transmission of an object in accordance with another embodiment of the present invention where the device has a stand-alone configuration. In this embodiment the body 2 of the measuring device is designed to be hand-held and comprises at least one predominantly flat surface on which two sensors 9, 10 are positioned, and is furthermore provided with a display 16, an internal battery 17, buttons 18, 19 and a control unit 41. The control unit 41 may receive, store and process data output from each of the sensors 9, 10. The control unit may also be described as a measurement and control unit. The control unit may further calculate a sensor sensitivity, an optical transmission value and/or a soiling loss based on the sensor outputs. The display 16 and the buttons 18, 19 are optional features. The display 16 and the buttons 18, 19 may be connected to the control unit. In the illustrated embodiment, the display provides a visual representation of the results to a user. The button 18 is a user-control for a user to control what is shown on the display. The button 19 is a switching arrangement to initiate capture of outputs from the first and second sensors 9, 10.

FIG. 3 shows a system 40 for measuring optical transmission of a reference object comprising a measuring device 1 of FIG. 1 having the sensors 9, 10 in combination with a reference object 21. The reference object 21 is a transparent plate having a front surface 22 that may be subject to soiling and a rear surface 27. The measuring device 1 is mounted at the rear surface 27 where it is protected from soiling by a housing 42. An actuator 50 is also provided and arranged to move the measuring device 1 out of the housing 42 for the purpose of performing measurements.

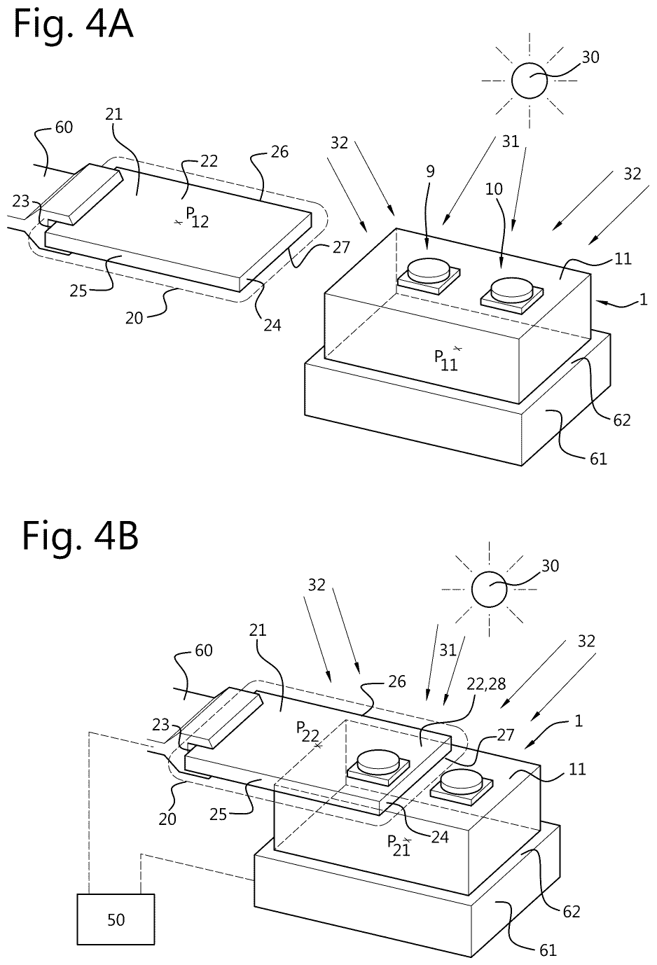

FIG. 4A shows a perspective view of a measuring device 1 of FIG. 1 or FIG. 2 in use in a first step of measurement for determining optical transmission of an object 21, according to the invention. Although only the sensors 9, 10 of the measuring device 1 are shown, the measuring device 1 should be understood as comprising any of the features presented in FIG. 1 or FIG. 2. The object 21 to be analyzed comprises six sides 22, 23, 24, 25, 26, 27 and is positioned in a measuring area 20 at a position P₁₂ (defined for the illustration as the centre point of the object 21) such that a perpendicular projection of the measuring area 20 on the measurement plane 11 does not overlap with any of the sensors 9, 10 on the body 2 of the measuring device 1. The body 2 is located at a position P₁₁ (defined for the illustration as the centre point of the body 2) with P₁₁ different from P₁₂. The object 21 is held at its position P₁₂ by gripping means 60 illustrated as a clamp. In other embodiments the object may be held at the position P₁₂ by other gripping means 60 such as a surface projection or handle of the object 21 held by the hand of a user holding the object 21. The body 2 is shown to be supported at the position P₁₁ by surface 62 of a support structure 61. The surface 62 is substantially flat and may comprise fixing means to fix the body 2 on the surface so that it does not fall. In other embodiments the object 21 may supported by a similar support structure instead of the clamp or gripping means 60. This may include a frame or any other structure known to the skilled person to hold the object to be measured at a predetermined location and comprising at least a surface 62 on which the object is fixed. This surface 62 may also be inclined provided that the sensors 9, 10 are exposed to the light. In other embodiments the body 2 may be held by gripping means at the position P₁₂ instead of a support structure 61 supporting it. In this first step the sensors 9, 10 of the measuring device are exposed to light from an external source 30 and the sensors generate respective outputs corresponding to the measured light. In the illustrated case the external source 30 is the sun and both sensors 9, 10 of the measuring device measure both direct light 31 and diffuse light 32 received from the sun. Manual reading of the sensor outputs at this position is initiated by actuation of the switching arrangement provided by button 19 or by the control unit 41 in combination with an appropriate position sensor of the actuator 50.

FIG. 4B shows a perspective view of the measuring device 1 of FIG. 1 or FIG. 2 in use in a second step of measurement for determining optical transmission of the object 21, according to an embodiment of the invention. The object 21 held by gripping means 60, i.e the clamp, has been moved from the position P₁₂ to a position P₂₂ and the body 2 has been moved from the position P₁₁ to position P₂₁. The movement has been imparted by an actuator 50 to the gripping means 60 and to the support structure 61 for the measuring area 20 and body 2 to reach the required positions P₂₁, P₂₂. In other embodiments, only the measuring device 1 or only the measuring area 20 may move. Alternatively, the movement may be imparted manually by a user instead of by an actuator 50. In this new configuration, the perpendicular projection of the measuring area 20 overlaps one sensor 9 of the pair of sensors 9, 10. The measuring area 20 does not overlap the other sensor 10 of the pair. This other sensor 10 has therefore a field of view that is, as in the first step of measurement, unobstructed by the object 21. Surface 22 of the object 21 is defined as a measurement side 28 for optical transmission, onto which direct 31 and/or diffuse light 32 is incident. In response to actuation of the switching arrangement provided by button 19 or by the control unit 41 in combination with an appropriate position sensor of the actuator 50, the sensors 9, 10 measure light irradiance and generate respective outputs that correspond to the light measured at this position.

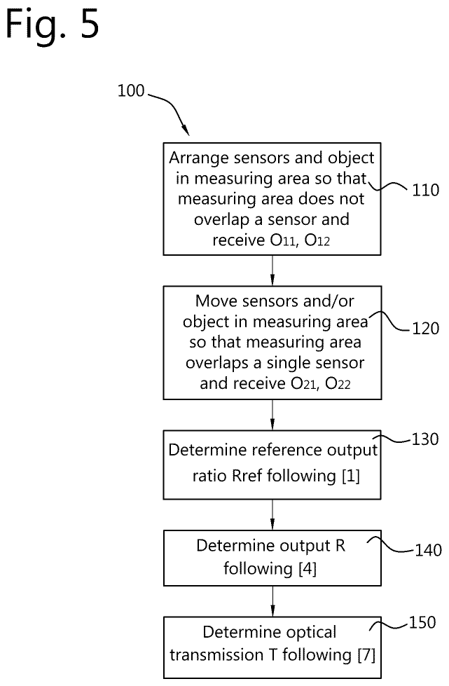

FIG. 5 shows a flowchart of a method 100 of determining optical transmission through an object carried out by the control unit 41, according to an embodiment of the present invention.

In step 110 of the method, the measuring device 1 according to the embodiment of FIG. 1 or FIG. 2 is arranged relative to the object 21 in a measuring area 20 so that a perpendicular projection of the measuring area 20 does not overlap with any of the sensors 9, 10 of the device, as shown in FIG. 4A and first and second sensor outputs O₁₁, O₁₂ are generated that are characteristic of a light intensity measured at each of the two sensors.

In step 120 of the method, the measuring device 1 and/or the object 21 in the measuring area 20 are moved so that a perpendicular projection of the measuring area overlaps with a first of the two sensors 9, 10 of the measuring device as shown in FIG. 4B and third and fourth outputs O₂₁, O₂₂ are generated that are characteristic of a light intensity transmitted through the object 21 and measured by the first sensor 9, and characteristic of a light intensity measured by the second sensor 10, respectively.

In step 130 of the method, a reference ratio R_{ref} is calculated based on the sensor outputs O₁₁, O₂₁ measured by sensors 9, 10 on a measurement side in the first step of the method, where fields of view of both sensors 9, 10 are unobstructed by the object to be analysed:

$${R}_{ref} = {O}_{11} / {O}_{12} \qquad [ 1 ]$$

Where each output is defined as a product:

$${O}_{11} = {S}_{1} {I}_{1 ,} \qquad [ 2 ]$$

$${O}_{12} = {S}_{2} {I}_{1} , \qquad [ 3 ]$$

Where S₁, S₂ corresponds to the respective sensitivities of sensors 9, 10 and I₁ the irradiance of the external light source during the first measurement step.

In step 140 of the method, a measurement ratio R is calculated based on the sensor outputs O₂₁, O₂₂ measured by sensors 9, 10 on a measurement side in the second step of the method, where the object 21 to be analysed overlaps one of the sensors 9, and the other sensor's 10 field of view is unobstructed by the object:

$$R = {O}_{21} / {O}_{22} \qquad [ 4 ]$$

Where each output is defined as a product:

$${O}_{21} = {S}_{1} T {I}_{2} , \qquad [ 5 ]$$

$${O}_{22} = {S}_{2} {I}_{2} , \qquad [ 6 ]$$

Where S₁, S₂ corresponds to the respective sensitivities of sensors 9, 10, T the optical transmission and I₂ the irradiance of the external light source during the second measurement step.

In steps 130 and 140 corrections may be applied for R_{ref} not equal to 1.

In step 150 of the method the optical transmission T is calculated based on the calculated measurement ratio R and reference ratio R_{ref} following:

$$T = R / {R}_{ref} \qquad [ 7 ]$$

Steps 130 to 150 of the method may be carried out by a control unit 41 such as the one in the stand alone device of FIG. 2 or by a system comprising a control unit 41 such as the one of FIG. 3.

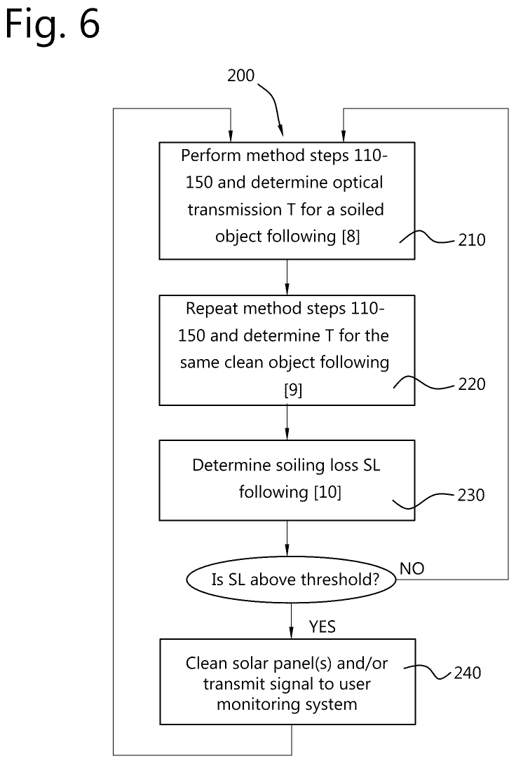

FIG. 6 shows a flowchart of a method 200 of determining soiling loss of a cover layer for photovoltaic panels according to an embodiment of the present invention. The cover layer is mounted in a plane array of a photovoltaic power plant, the cover layer being preferably a glass or a plastic cover layer, in a soiled condition. The method may be carried out by a control unit such as the one in the stand alone device of FIG. 2 or in the system comprising the device such as the one of FIG. 3.

In step 210 of the method, optical transmission T of the soiled cover layer is determined following steps 110-150 according to the method of determining optical transmission.

$$T = R / {R}_{ref} \qquad [ 8 ]$$

In step 220 of the method, optical transmission T_{clean} of a cover layer of the same type in a cleaned condition is determined following steps 110-150 according to the method of determining optical transmission to obtain R_{ref, clean} and R_{clean}.

$${T}_{clean} = {R}_{clean} / {R}_{ref , clean} \qquad [ 9 ]$$

In step 230 of the method, soiling loss SL of the cover layer is calculated based on the comparison of the transmission through the soiled cover layer, and the transmission through a cover layer of the same type, in a clean state following:

$$S [ \% ] = 100 ( {T}_{clean} - T ) {T}_{clean} \qquad [ 10 ]$$

Alternatively, step 220 may be performed before step 210 when the cover layer has just been placed in the field before it gets soiled, or the value T_{clean} may be taken from literature or product specifications.

If the calculated soiling loss is above a predetermined threshold, in step 240 of the method, a device may be actuated to clean covers of neighbouring solar panels and/or data transmitted to a user monitoring system to warn a user that cleaning should be performed. After a predetermined time after cleaning or transmitting the result, the method may restart at step 210. If the calculated soiling loss is below a predetermined threshold, the method may also restart at step 210.

1. A system comprising a measuring device for measuring optical transmission, T, through an object positioned in a measuring area between an external light source and the measuring device, the measuring device comprising:
i. a body, two sensors placed on the body and being situated in a measurement plane, the two sensors having the same spectral and directional response; and
ii. a control unit, operatively connected to the sensors to receive respective sensor outputs;
wherein the body is configured to be moved between a first position in which a perpendicular projection of the measuring area onto the body does not overlap with either of the sensors, and a second position in which the projection of the measuring area overlaps with one sensor but not with the other sensor and the control unit is adapted to calculate a value T of the optical transmission of the object based on changes in the ratio of the sensor outputs of the sensors.

2. The system according to claim 1, further comprising an actuator adapted to move the measuring area and/or the body relative to one another between the first position and the second position.

3. The system according to claim 2, wherein the actuator comprises an electro-mechanical or mechanical translator providing incremental movement to the measuring area or the body between the first and the second position.

4. The system according to claim 1, wherein at least one of the measuring area and the body comprises gripping means or a support structure to which a motion can be imparted to transport the measuring area or the body from the first position to the second position and vice-versa, wherein the gripping means comprise at least one of a projection or a clamp element to hold the measuring area or the body at a predetermined height and the support structure comprises at least a surface onto which the measuring area or the body is fixed.

5. (canceled)

6. The system according to claim 1, wherein the sensors are pyranometers according to ISO 9060.

7. The system according to claim 1, wherein each of the sensors comprises a photodiode or a solar cell or a reference cell according to IEC 60904-2, made of at least one of silicon, germanium, indium gallium arsenide, amorphous silicon (a-Si)·copper-indium gallium diselenide, copper zinc tin sulfide/selenide, cadmium telluride or Perovskite or of one of their alloys.

8. The system according to a claim 1, wherein at least one of the sensors is equipped with front optics selected from: a lens, a view limiting aperture or a diffuser.

9. The system according to claim 1, wherein the control unit is adapted to calculate the value of the optical transmission, T=R/R_{ref}, of the object based on a ratio R_{ref}=O₁₁/O₁₂, where O₁₁ and, O₁₂ are respectively the outputs of the two sensors; when the measuring device is in the first position and on a ratio R=O₂₁/O₂₂, where O₂₁ and O₂₂ are respectively the outputs of the two sensors when the measuring device is in the second position, and further comprising a power supply for powering the control unit.

10. The system according to claim 1, wherein the body is further provided with a display connected to the control unit.

11. The system according to claim 1, further comprising a transparent reference object, wherein the measuring device is arranged to calculate a value of the optical transmission of the reference object.

12. A method of determining optical transmission, T, of an object positioned in a measuring area exposed to incident light radiation, the method comprising:
providing a measuring device comprising two sensors placed on a body, the two sensors being situated in a measurement plane and having the same spectral and directional response,
arranging the measuring device at a first position relative to the measuring area so that both sensors are exposed to light of equal intensity,
receiving first and second sensor outputs that are characteristic of a light intensity measured at each of the two sensors,
moving the measuring device to a second position relative to the measuring area so that a first of the two sensors receives light transmitted through the object and a second of the two sensors receives unobstructed light,
receiving a third output that is characteristic of a light intensity transmitted through the object and measured by the first sensor, and a fourth output that is characteristic of a light intensity measured by the second sensor,
determining the optical transmission, T, of the object by evaluating the sensor outputs.

13. The method of claim 12, wherein arranging the measuring device relative to the measuring area so that both sensors are exposed to light of equal intensity comprises arranging the measuring device so that a perpendicular projection of the measuring area does not overlap with either of the sensors.

14. The method of claim 12, wherein determining the optical transmission of the object comprises:
determining a ratio, R_{ref}=O₁₁/O₁₂, where O₁₁ and O₁₂ are the first and second outputs;
determining a ratio, R=O₂₁/O₂₂, where O₂₁ and O₂₂ are the third and fourth outputs;
determining the optical transmission, T, of the object using T=R/R_{ref}.

15. The method according to claim 12, wherein arranging the measuring device relative to the measuring area further comprises providing an angle of between 45 and 90° between the measurement plane and the incident light.

16. The method of claim 12, wherein the object is a reference object and the soiling loss of a photovoltaic panel is determined by:
determining the optical transmission, T, of the transparent reference object mounted adjacent to the photovoltaic panel;
determining the optical transmission, T_{clean}, of the reference object in a clean condition, or using a predetermined clean transmission value T_{clean}; and
calculating a soiling loss using (T_{Clean}−T)/(T_{Clean}).

17. (canceled)

18. The method according to claim 16, wherein the reference object is a glass or plastic cover layer, that has been mounted adjacent and exposed to the same environmental soiling as the photovoltaic panel.

19. The method according to claim 18, wherein a front surface of the reference object is exposed to incident light and soiling and a rear surface of the reference object is protected from soiling, wherein the measuring device is mounted at a rear surface of the reference object and can be actuated to cause at least one of the light sensors to extend from behind the reference object and be exposed to incident radiation.

20. (canceled)

21. The method according to claim 16, wherein the measuring device is a handheld instrument and a user moves the measuring device between the first position and the second position and manually initiates capture of the first and second sensor outputs at the respective positions.

22. The method according to claim 16, wherein the method further comprises actuating a cleaning device or implementing a cleaning procedure, to clean cover layers of photovoltaic panels or transmitting a signal to a user monitoring system, when the result of the calculated soiling loss exceeds a predetermined threshold.

23. (canceled)

24. A measuring device for measuring optical transmission, T, through an object positioned in a measuring area between an external light source and the measuring device, the measuring device comprising:
i. a body, two matched sensors placed on the body and being situated in a measurement plane; and
ii. a control unit, operatively connected to the sensors to receive respective sensor outputs;
wherein the body is configured to be moved between a first position in which a perpendicular projection of the measuring area onto the body does not overlap with either of the sensors, and a second position in which the projection of the measuring area overlaps with one sensor but not with the other sensor and the control unit is adapted to calculate a value T of the optical transmission of the object based on changes in the ratio of the sensor outputs of the sensors using the equation T=R/R_{ref}, R=O₂₁/O₂₂, where O₂₁ and O₂₂ are the third and fourth outputs being characteristic of a light intensity measured at each of the two sensors in the second position, and R_{ref}=O₁₁/O₁₂, where O₁₁ and O₁₂ are the first and second outputs being characteristic of a light intensity measured at each of the two sensors in the first position.
